(19) United States
(12) Patent Application Publication
(10) Pub. No.: US 2024/0203920 A1
(43) Pub. Date: Jun. 20, 2024

(54) SEMICONDUCTOR DEVICE AND Manufacturing METHOD THEREOF

(71) Applicant: EPISTAR CORPORATION, Hsinchu (TW)

(72) Inventors: Min-Hsun HSIEH, Hsinchu (TW); Shih-An LIAO, Hsinchu City (TW); Jan-Way CHIEN, Hsinchu (TW)

(21) Appl. No.: 18/537,508

(22) Filed: Dec. 12, 2023

(30) Foreign Application Priority Data
Dec. 14, 2022 (TW) 111147894

(51) Int. Cl. H01L 23/00

(52) U.S. Cl. CPC H01L 24/13; H01L 24/03; H01L 24/05; H01L 24/11; H01L 24/14; H01L 2224/0347; H01L 2224/03848; H01L 2224/0401; H01L 2224/05557; H01L 2224/05624; H01L 2224/11515; H01L 2224/13016; H01L 2224/13111; H01L 2224/13144; H01L 2224/1403

(57) ABSTRACT

The present disclosure provides a semiconductor device. The semiconductor device includes a first electrode and a second electrode disposed on a substrate, a first conductive bump disposed on the first electrode, and a second conductive bump disposed on the second electrode, wherein, the first conductive bump has a first convex top surface, the second conductive bump has a second convex top surface, and the top of the first convex top surface and the top of the second convex top surface substantially have a same horizontal height. The composition of the first electrode includes a first metal. The composition of the first conductive bump includes the first metal and a second metal. The content of the first metal in the first conductive bump is gradually decreased in a direction away from the first electrode.

### CROSS-REFERENCE TO RELATED APPLICATIONS

This application claims priority to the benefit of Taiwan Patent Application Number 111147894 filed on Dec. 14, 2022, the entire content of which is hereby incorporated by reference herein in its entirety.

### TECHNICAL FIELD

The present disclosure relates to a semiconductor device, and more particularly, to an electrical connection structure of the semiconductor device and the manufacturing method thereof.

### DESCRIPTION OF BACKGROUND ART

In a semiconductor manufacturing process, conductive wires located on dielectric layers at different horizontal heights are usually connected by conductive materials filled in the vertical holes in the dielectric layers. However, to completely fill these holes having different depths with conductive materials and then form flat surfaces at the openings of these holes often requires a multi-step manufacturing process, which is complicated and expensive.

In addition, in a package structure of semiconductor chips, conductive bumps are usually used to produce electrical connections with external circuits. However, the present manufacturing method of forming conductive bumps is often unable to accurately control the height of the conductive bumps, resulting in the tops of multiple conductive bumps of a semiconductor chip not being coplanar, which in turn affects the production yield of the semiconductor package structures.

### SUMMARY OF THE APPLICATION

In view of this, the embodiments disclosed in the present disclosure provide methods for accurately controlling the dimensions of the electrical connection structure of a semiconductor device, for example, by accurately controlling the height of several conductive bumps in a semiconductor device, and by providing a semiconductor device manufactured by these manufacturing methods.

According to one embodiment of the present disclosure, a semiconductor device is provided. The semiconductor device includes a substrate, a first electrode, a second electrode, a first conductive bump, and a second conductive bump. The first electrode and the second electrode are disposed on the substrate. The first conductive bump is disposed on the first electrode and the second conductive bump is disposed on the second electrode. Wherein, the first conductive bump includes a first convex top surface, the second conductive bump includes a second convex top surface, and a top of the first convex top surface and a top of the second convex top surface substantially have a same horizontal height; wherein, the compositions of the first electrode and the second electrode include a first metal, the compositions of the first conductive bump and the second conductive bump include the first metal and a second metal, and the content of the first metal in the first conductive bump is gradually decreased in a direction away from the first electrode.

According to another embodiment of the present disclosure, a semiconductor device is provided. The semiconductor device includes a substrate, a first electrode, a second electrode, a first conductive bump, and a second conductive bump. The first electrode and the second electrode are disposed on the substrate. The first conductive bump is disposed on the first electrode and the second conductive bump is disposed on the second electrode. A first metal film is located at one side of the first conductive bump; and a second metal film is located at one side of the second conductive bump.

According to another embodiment of the present disclosure, a method of manufacturing a semiconductor device is provided. The method includes providing a semiconductor chip, and the semiconductor chip including a first electrode and a second electrode; forming a first metal layer on the first electrode, the first metal layer including a first part and a second part, in an upper view, the first part overlapping the first electrode, and the second part not overlapping the first electrode; and heating the first metal layer so that a thickness of the first part increasing and a thickness of the second part decreasing.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1 illustrates a cross-sectional view of some stages of one manufacturing method of a semiconductor device in accordance with an embodiment of the present disclosure.

FIG. 2 illustrates a cross-sectional view of some stages of one manufacturing method of a semiconductor device in accordance with another embodiment of the present disclosure.

FIG. 3 illustrates a cross-sectional view of a semiconductor device and an enlarged cross-sectional view of region A in accordance with an embodiment of the present disclosure.

FIG. 4 illustrates a cross-sectional view of a semiconductor device in accordance with another embodiment of the present disclosure.

FIG. 5 illustrates a cross-sectional view of a semiconductor device in accordance with another embodiment of the present disclosure.

FIG. 6 illustrates a cross-sectional view of a semiconductor device in accordance with another embodiment of the present disclosure.

FIG. 7 illustrates a cross-sectional view of some stages of one manufacturing method of a semiconductor device in accordance with another embodiment of the present disclosure.

FIG. 8 illustrates an upper view of a semiconductor device in accordance with one embodiment of the present disclosure.

FIG. 9 illustrates a cross-sectional view of a semiconductor device along the line segment I-I of FIG. 8 in accordance with an embodiment of the present disclosure.

FIG. 10 illustrates a graph of the heights of the conductive bumps of a semiconductor device corresponding to the projected areas of the metal layers in accordance with some embodiments of the present disclosure.

### DETAILED DESCRIPTION OF THE APPLICATION

The semiconductor devices and manufacturing methods thereof in accordance with the embodiments of the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

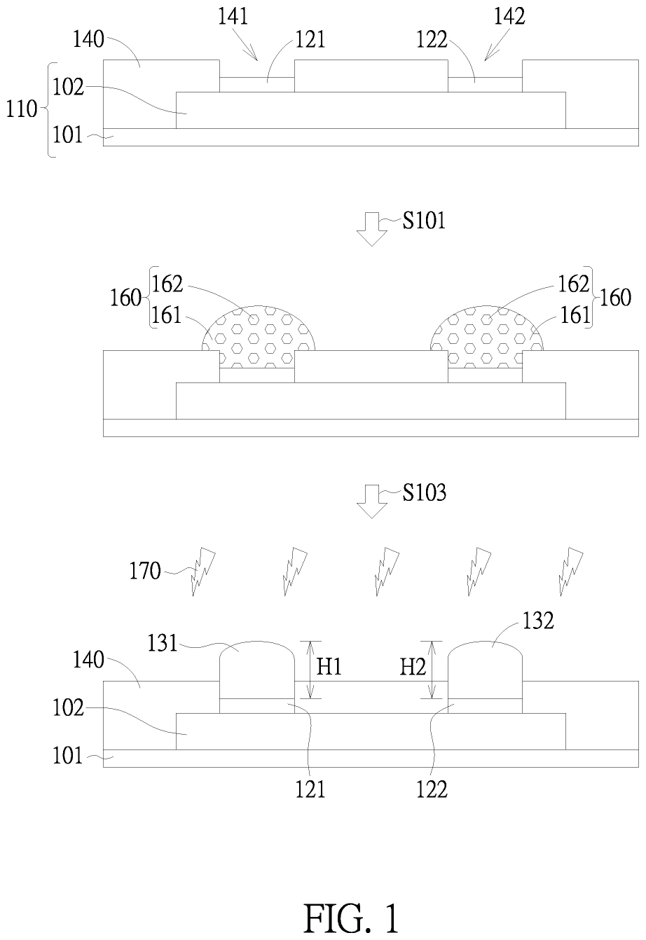

FIG. 1 illustrates a cross-sectional view of some stages of one manufacturing method of a semiconductor device in accordance with an embodiment of the present disclosure. First, a carrier 101 is provided, and a semiconductor chip 102 is formed on the carrier 101. In some embodiments, the carrier 101 includes a material for epitaxial growth, a material for non-epitaxial growth, a growth substrate, or a non-growth substrate. Wherein, the material for epitaxial growth or a growth substrate may be, for example, silicon (Si), germanium (Ge), lithium aluminate (LiAlO₂), zinc oxide (ZnO), silicon carbide (SiC), Sapphire, gallium nitride (GaN), aluminum nitride (AlNₓ), gallium arsenide (GaAs), or indium phosphide (InP); the material for non-epitaxial growth or a non-growth substrate may be, for example, a ceramic substrate, metal, glass, a thermal release tape, an UV release tape, a chemical release tape, a heat-resistant tape, a blue tape, or a dynamic release layer (DRL). The semiconductor chip 102 may be a light-emitting diode (LED), a laser diode (LD), a transistor, and so on.

In addition, the first electrode 121 and the second electrode 122 are formed on a same side of the semiconductor chip 102. A dielectric layer 140 is formed on the carrier 101 and the semiconductor chip 102 and includes a first hole 141 and a second hole 142 which expose the first electrode 121 and the second electrode 122, respectively. The dielectric layer 140 may be a single-layer or a multi-layer structure and has the characteristic of electrical insulation. The material of the single-layer structure may include, for example, oxides, nitrides, nitrogen oxides, or polymers. Oxides may include, for example, aluminum oxide (AlOₓ), silicon dioxide (SiO₂), titanium dioxide (TiO₂), or tantalum pentoxide (Ta₂O₅). Nitrides may include, for example, aluminum nitride (AlNₓ) or silicon nitride (SiNₓ). Nitrogen oxides may include, for example, aluminum nitrogen oxide (AlOₓN_{y}) or silicon nitrogen oxide (SiOₓN_{y}). Polymers may include, for example, polyimide (PI), epoxy resin (polyepoxide; EPO), polybenzoxazole (PBO), polysiloxane, cyclic olefin polymer (COP), or benzocyclobutane (BCB). The materials of the multi-layer structure may include, for example, a combination of the stacks of the aforementioned materials.

Then, in step S101, conductive glue 160 can be filled in the first hole 141 and the second hole 142 by means of printing, coating, spraying, dispensing, and so on. In this embodiment, the conductive glue 160 includes an insulating glue 161 and a plurality of conductive particles 162 dispersed in the insulating glue 161, and the material of the conductive particles 162 may be, for example, tin (Sn), silver (Ag), gold (Au), copper (Cu), or a metal alloy. Metal alloy may be, for example, tin-indium (Sn—In) alloy or tin-bismuth (Sn—Bi) alloy. The insulating glue 161 includes a thermosetting plastic and a flux. The thermosetting plastic may be, for example, EPO, silicone, or polymethylmethacrylate (PMMA).

The flux may be, for example, rosin or episulfide. The melting point of the conductive particle 162 is lower than the curing temperature of the insulating glue 161.

Then, in step S103, energy 170 is provided to irradiate and heat the conductive glue 160, the first electrode 121, and the second electrode 122 to form a first conductive bump 131 on the first electrode 121 and a second conductive bump 132 on the second electrode 122. Energy 170 may be, for example, ultraviolet (UV) laser beam, visible laser beam, or infrared (IR) laser beam. In one embodiment, energy 170 is a pulse mode IR laser beam with wavelengths ranging from 750 nm to 2,000 nm, a spot size of 0.004 to 0.002 cm², a beam diameter of 100 to 500 μm, a pulse width of less than 20 milliseconds (ms), a frequency of 500 to 4000 Hz, a duty cycle of 1% to 10%, a power of 100 W, and an energy of 595 to 850 J/cm².

In the heating process, before the insulating glue 161 is completely cured, the conductive particles 162 aggregate on the first electrode 121 and the second electrode 122 to form a first conductive bump 131 and a second conductive bump 132 which include convex top surfaces, respectively. Meanwhile, the insulating glue 161 moves to the area between the first electrode 121 and the second electrode 122 and on the first conductive bump 131 and the second conductive bump 132. After the heating process is finished, the first conductive bump 131 and the second conductive bump 132 are cured while the insulating glue 161 is not completely cured and presents a liquid or a semi-liquid state.

A cleaning step may also be proceeded in step 103 to remove the insulating glue 161 that is not fully cured. The cleaning step can be proceeded with a solvent, such as N-methylpyrrolidone (NMP), methyl ethyl ketone (MEK), acetone (ACE), or isopropyl alcohol (IPA).

According to an embodiment, the projected areas and the depths of the first hole 141 and the second hole 142 in the dielectric layer 140 and the amount of conductive glue 160 can be adjusted to control the height H1 of the first conductive bump 131 and the height H2 of the second conductive bump 132, make the total volume of the first conductive bump 131 greater than that of the first hole 141 and the total volume of the second conductive bump 132 greater than that of the second hole 142.

In one embodiment, the height H1 of the first conductive bump 131 and the height H2 of the second conductive bump 132 are substantially the same. For example, when the top surfaces of the first electrode 121 and the second electrode 122 have a same horizontal height, the height H1 of the first conductive bump 131 and the height H2 of the second conductive bump 132 can be substantially the same, so that the top of the first conductive bump 131 and the top of the second conductive bump 132 substantially have a same horizontal height. In another embodiment, the height H1 of the first conductive bump 131 and the height H2 of the second conductive bump 132 are different. For example, when the top surfaces of the first electrode 121 and the second electrode 122 are at different horizontal heights, the height H1 of the first conductive bump 131 and the height H2 of the second conductive bump 132 can be different, so that the top of the first conductive bump 131 and the top of the second conductive bump 132 substantially have a same horizontal height.

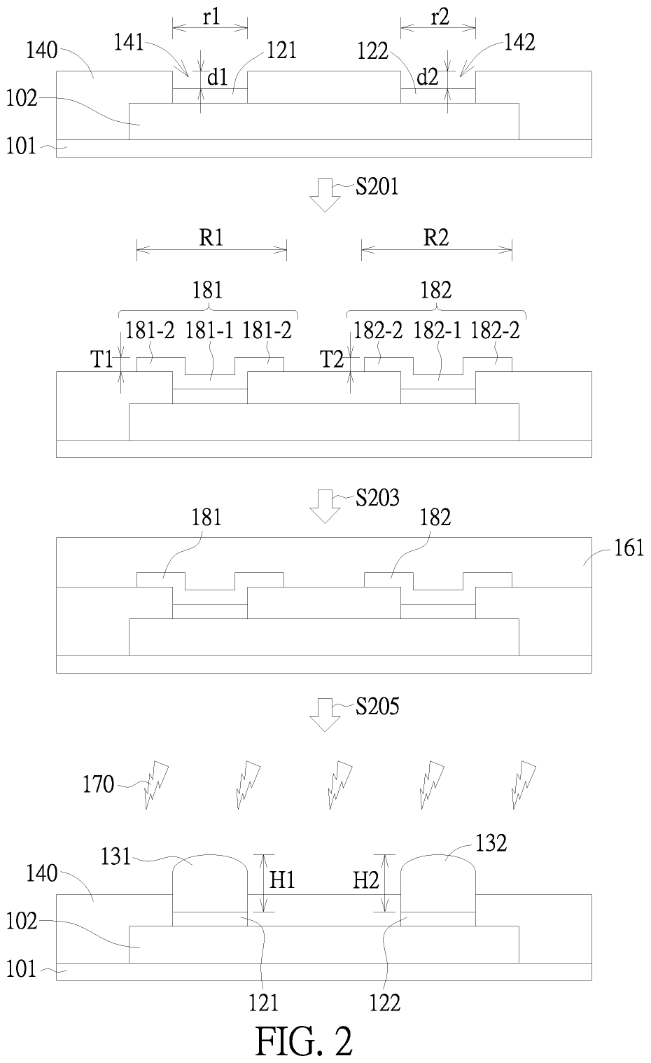

FIG. 2 illustrates a cross-sectional view of some stages of one manufacturing method of a semiconductor device in accordance with another embodiment of the present disclosure. First, a carrier 101 is provided, a semiconductor chip 102 is formed on the carrier 101, and a first electrode 121 and a second electrode 122 are formed on a same side of the semiconductor chip 102. Then, a dielectric layer 140 is formed on the carrier 101 and surrounds the semiconductor chip 102, which includes a first hole 141 and a second hole 142 to expose the first electrode 121 and the second electrode 122, respectively. The description of the carrier 101, the semiconductor chip 102, and the dielectric layer 140 can be referred to the above relevant paragraphs of FIG. 1. In one embodiment, the first hole 141 has a first area r1 and a first depth d1, and the second hole 142 has a second area r2 and a second depth d2. The first area r1 refers to a projected area of the first hole 141 on the carrier 101 or an area of the first hole 141 in an upper view of the semi-finished semiconductor device, and the second area r2 refers to a projected area of the second hole 142 on the carrier 101 or an area of the second hole 142 in an upper view of the semi-finished semiconductor device.

Then, in step S201, a first metal layer 181 can be formed on the first electrode 121 and a second metal layer 182 can be formed on the second electrode 121 by using a photolithography process and an evaporation process. For example, using the photolithography process to form a photoresist layer with openings on the dielectric layer 140 (not shown), the openings of the photoresist layer expose the first electrode 121, the second electrode 122, and the dielectric layer 140 around the first electrode 121 and the second electrode 122, and then a metal material layer is deposited in the openings of the photoresist layer by using the evaporation process to make the metal material layer contact the first electrode 121, the second electrode 122, and the dielectric layer 140 around the first electrode 121 and the second electrode 122. Then, the photoresist layer is removed. The formed first metal layer 181 includes a first part 181-1 and a second part 181-2, and the formed second metal layer 182 includes a third part 182-1 and a fourth part 182-2. In an upper view, the first part 181-1 overlaps the first electrode 121, the second part 181-2 does not overlap the first electrode 121, the third part 182-1 overlaps the second electrode 122, and the fourth part 182-2 does not overlap the second electrode 122. In one embodiment, the first metal layer 181 has a first area R1 and a first thickness T1, and the second metal layer 182 has a second area R2 and a second thickness T2. The first area R1 refers to a projected area of the first metal layer 181 on the carrier 101 or an area of the first metal layer 181 in an upper view of the semi-finished semiconductor device, and the second area R2 refers to a projected area of the second metal layer 182 on the carrier 101 or an area of the second metal layer 182 in an upper view of the semi-finished semiconductor device.

Then, in one embodiment, step S203 is optionally proceeded. A glue that does not contain conductive particles, for example, an insulating glue 161, can be comprehensively applied to the dielectric layer 140, the first metal layer 181, and the second metal layer 182 by printing, coating, spraying, dispensing, and so on. In one embodiment, the insulating glue 161 has an anti-oxidation function for metal and helps the first metal layer 181 and the second metal layer 182 to liquefy and aggregate toward the first electrode 121 and the second electrode 122, respectively. In another embodiment, step S203 may be omitted. That is, an insulating glue 161 may not be applied to the first metal layer 181 and the second metal layer 182.

Then, in step S205, energy 170 is provided to irradiate and heat the insulating glue 161, the first metal layer 181, the second metal layer 182, the first electrode 121, and the second electrode 122 to form a first conductive bump 131 on the first electrode 121 and a second conductive bump 132 on the second electrode 122. The conditions of applying energy 170 can be referred to the above relevant paragraphs in step S103. During the heating process, the first metal layer 181 aggregates toward the top of the first electrode 121, and the second metal layer 182 aggregates toward the top of the second electrode 122, so that the thickness of the first part 181-1 of the first metal layer 181 increases, and the thickness of the second part 181-2 of the first metal layer 181 decreases, and the thickness of the third part 182-1 of the second metal layer 182 increases, and the thickness of the fourth part 182-2 of the second metal layer 182 decreases, and a first conductive bump 131 and a second conductive bump 132 with outer convex top surfaces are formed. Meanwhile, the insulating glue 161 moves to the area between the first electrode 121 and the second electrode 122 and on the first conductive bump 131 and the second conductive bump 132 (not shown). After heating, the first conductive bump 131 and the second conductive bump 132 can be cured, and the insulating glue 161 is not completely cured and is in a liquid or semi-liquid state. In step S205, a cleaning step can also be proceeded by using the solvent described above to remove the uncured insulating glue 161.

According to one embodiment, the product of the first area R1 and the first thickness T1 of the first metal layer 181 is greater than the product of the first area r1 and the first depth d1 of the first hole 141, the product of the second area R2 and the second thickness T2 of the second metal layer 182 is greater than the product of the second area r2 and the second depth d2 of the second hole 142, the top surfaces of the first conductive bump 131 and the second conductive bump 132 are higher than the top surface of the dielectric layer 140, the total volume of the first conductive bump 131 is greater than the total volume of the first hole 141, and the total volume of the second conductive bump 132 is greater than the total volume of the second hole 142. In addition, according to one embodiment, the height H1 of the first conductive bump 131 can be controlled by adjusting the first area R1 and/or the first thickness T1 of the first metal layer 181, and the height H2 of the second conductive bump 132 can be controlled by adjusting the second area R2 and/or the second thickness T2 of the second metal layer 182. In one embodiment, the height H1 of the first conductive bump 131 and the height H2 of the second conductive bump 132 are substantially the same. In another embodiment, the height H1 of the first conductive bump 131 and the height H2 of the second conductive bump 132 are different.

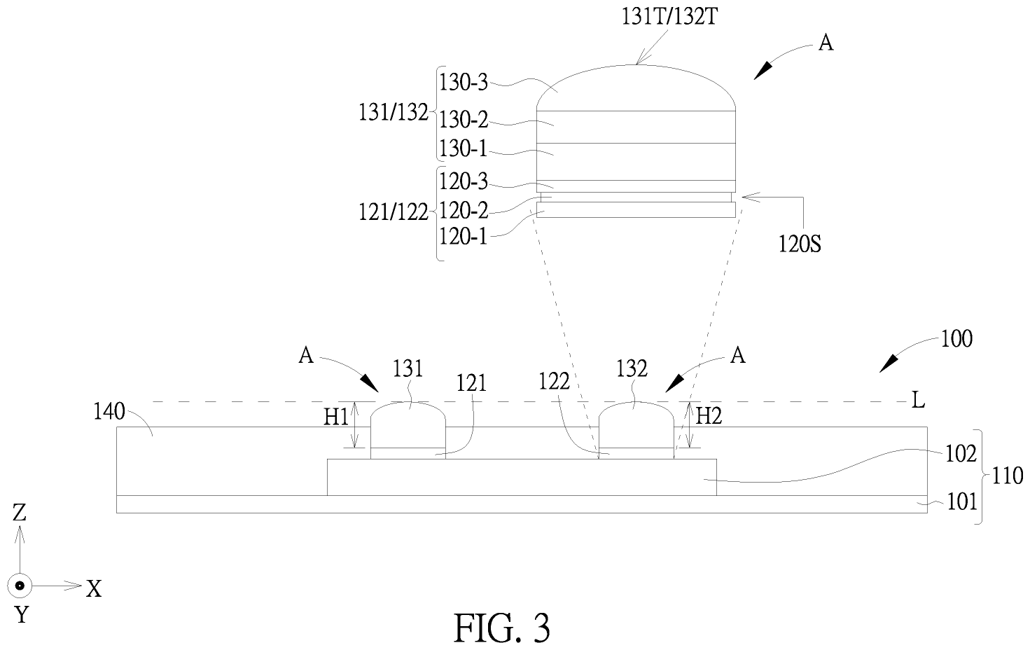

FIG. 3 illustrates a cross-sectional view of a semiconductor device and an enlarged cross-sectional view of region A in accordance with an embodiment of the present disclosure. As shown in FIG. 3, in one embodiment, the semiconductor device 100 includes a substrate 110, and the substrate 110 includes a carrier 101 and a semiconductor chip 102 disposed on the carrier 101. The semiconductor device 100 further includes a first electrode 121 and a second electrode 122 disposed on a same side of the semiconductor chip 102, a first conductive bump 131 is disposed on the first electrode 121, and a second conductive bump 132 is disposed on the second electrode 122.

In one embodiment, the first electrode 121 and the second electrode 122 each include a stacked structure composed of a plurality of metal layers. As the enlarged cross-sectional view of region A shown in FIG. 3, the first electrode 121 and the second electrode 122 each contain metal layers 120-1, 120-2 and 120-3 stacked from bottom to top. In one embodiment, the metal layer 120-1 may be, for example, chromium (Cr), nickel (Ni), gold (Au), titanium (Ti), platinum (Pt), or tin (Sn); the metal layer 120-2 may be, for example, aluminum (Al); and the metal layer 120-3 may be, for example, gold (Au), but it is not limited thereto. According to one embodiment, when the metal layer 120-2 contains Al, the first electrode 121 and the second electrode 122 are concave inward at the metal layer 120-2, as the depression 120S depicted in FIG. 3. Since solvents are usually used to remove the photoresist in the manufacturing process of forming the first electrode 121 and the second electrode 122, some of the solvents dissolve Al causes the Al-containing metal layer 120-2 to concave inwardly and results in a depression 120S. In addition, the first electrode 121 and the second electrode 122 are not limited to be stacked by three metal layers, and in other embodiments, the first electrode 121 and the second electrode 122 each include more than three metal layers, and each of the metal stacked structures of the electrodes includes an Al metal layer.

In addition, as the enlarged cross-sectional view of region A shown in FIG. 3, according to one embodiment, the first conductive bump 131 has a first convex top surface 131T, and the second conductive bump 132 has a second convex top surface 132T. When the tops of the first electrode 121 and the second electrode 122 substantially have a same horizontal height, the height H1 of the first conductive bump 131 and the height H2 of the second conductive bump 132 can be controlled by the manufacturing methods shown in FIGS. 1-2, so that the height H1 and the height H2 are the same, and then the top of the first convex top surface 131T of the first conductive bump 131 and the top of the second convex top surface 132T of the second conductive bump 132 substantially have a same horizontal height.

In addition, according to one embodiment, the compositions of the first electrode 121 and the second electrode 122 each include a first metal. The compositions of the first conductive bump 131 and the second conductive bump 132 each include the first metal and a second metal. The content of the first metal in the first conductive bump 131 decreases in the direction away from the first electrode 121, and the content of the first metal in the second conductive bump 132 decreases in the direction away from the second electrode 122. As the enlarged cross-sectional view of region A shown in FIG. 3, in one embodiment, each of the first conductive bump 131 and the second conductive bump 132 includes a bottom portion 130-1, a middle portion 130-2, and a top portion 130-3. The content of the first metal in the bottom portion 130-1 is higher than that of the first metal in the middle portion 130-2 and the content of the first metal in the middle portion 130-2 is higher than that of the first metal in the top portion 130-3. In one embodiment, the first metal is Au, the second metal is Sn, the composition of each bottom portion 130-1 of the first conductive bump 131 and the second conductive bump 132 is Au—Sn alloy, and the atomic percentages of Sn in the Au—Sn alloy may be 20% to 30%, so that the melting points of the first conductive bump 131 and the second conductive bump 132 are higher than the melting point of Sn.

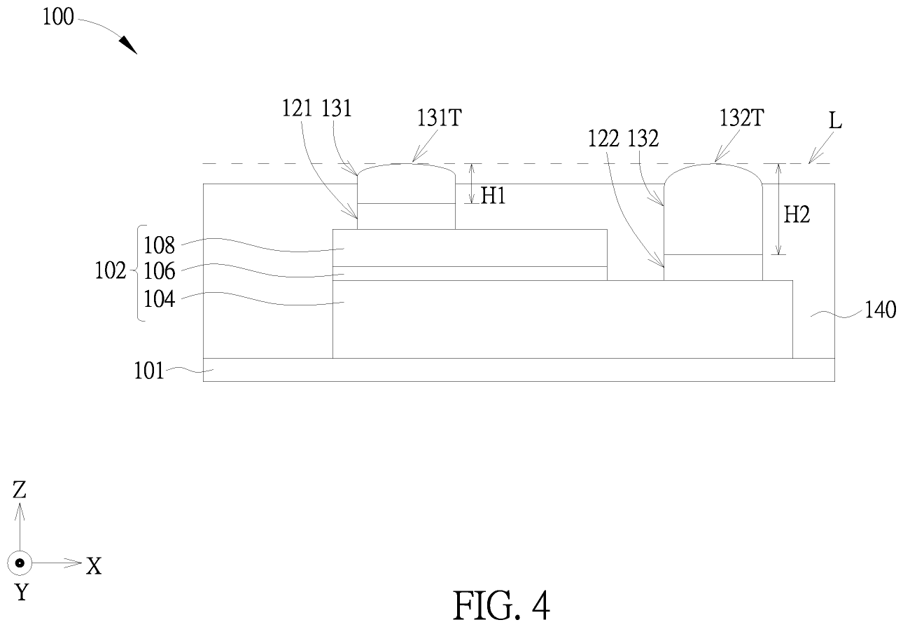

FIG. 4 illustrates a cross-sectional view of a semiconductor device in accordance with another embodiment of the present disclosure. In one embodiment, the semiconductor chip 102 of the semiconductor device 100 is a light-emitting diode chip. The light-emitting diode chip includes an n-type epitaxial layer 104, an active layer 106, and a p-type epitaxial layer 108 stacked sequentially from bottom to top. The first electrode 121 is a p-type electrode formed on the p-type epitaxial layer 108. The second electrode 122 is an n-type electrode formed on the n-type epitaxial layer 104, with a top surface lower than the top surface of the first electrode 121. The first conductive bump 131 is formed on the first electrode 121 and the second conductive bump 132 is formed on the second electrode 122. According to one embodiment, the height H1 of the first conductive bump 131 and the height H2 of the second conductive bump 132 can be controlled by the manufacturing methods shown in FIGS. 1-2 so the height H1 of the first conductive bump 131 is smaller than the height H2 of the second conductive bump 132, so that the top of the first convex top surface 131T of the first conductive bump 131 and the top of the second convex top surface 132T of the second conductive bump 132 substantially have a same horizontal height L. In addition, the semiconductor device 100 may also include a dielectric layer 140 disposed on the carrier 101 and a semiconductor chip 102. In one embodiment, the dielectric layer 140 surrounds the first electrode 121 and the second electrode 122. In another embodiment, the dielectric layer 140 also surrounds a portion of the first conductive bump 131 and a portion of the second conductive bump 132.

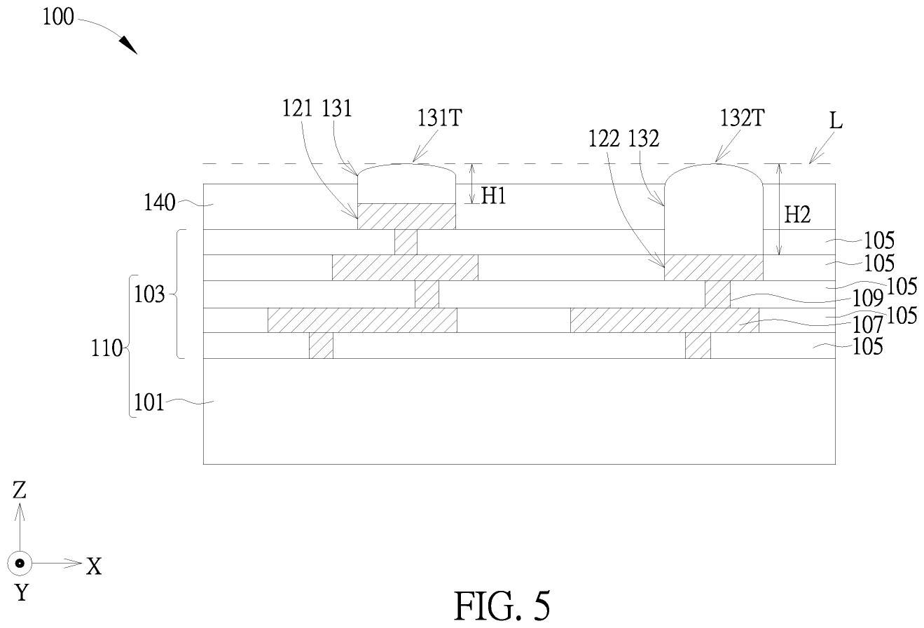

FIG. 5 illustrates a cross-sectional view of a semiconductor device in accordance with another embodiment of the present disclosure. In one embodiment, a substrate 110 of the semiconductor device 100 includes a carrier 101 and a redistribution layer (RDL) 103 formed on the carrier 101. In one embodiment, the carrier 101 is a substrate including semiconductor materials, and RDL 103 includes a plurality of dielectric layers 105 and a plurality of through holes (via) 109 and metal layers 107 located between the dielectric layers 105. Two adjacent metal layers 107 can be electrically connected to each other by metal materials filled in the through holes 109. The bottom surfaces of the first electrode 121 and the second electrode 122 of the semiconductor device 100 contact the top surfaces of the metal layers 107 at different horizontal heights. For example, the first electrode 121 may be located on a metal layer 107 in the redistribution layer 103 with a higher horizontal height, the second electrode 122 may be located on another metal layer 107 in the redistribution layer 103 with a lower horizontal height, and therefore the top surface of the first electrode 121 is higher than the top surface of the second electrode 122. The first conductive bump 131 is formed on the first electrode 121, and the second conductive bump 132 is formed on the second electrode 122. According to one embodiment, the height H1 of the first conductive bump 131 and the height H2 of the second conductive bump 132 can be controlled by the manufacturing methods shown in FIGS. 1-2 so the height H1 of the first conductive bump 131 is smaller than the height H2 of the second conductive bump 132, and the top of the first convex top surface 131T of the first conductive bump 131 and the top of the second convex top surface 132T of the second conductive bump 132 substantially have a same horizontal height L.

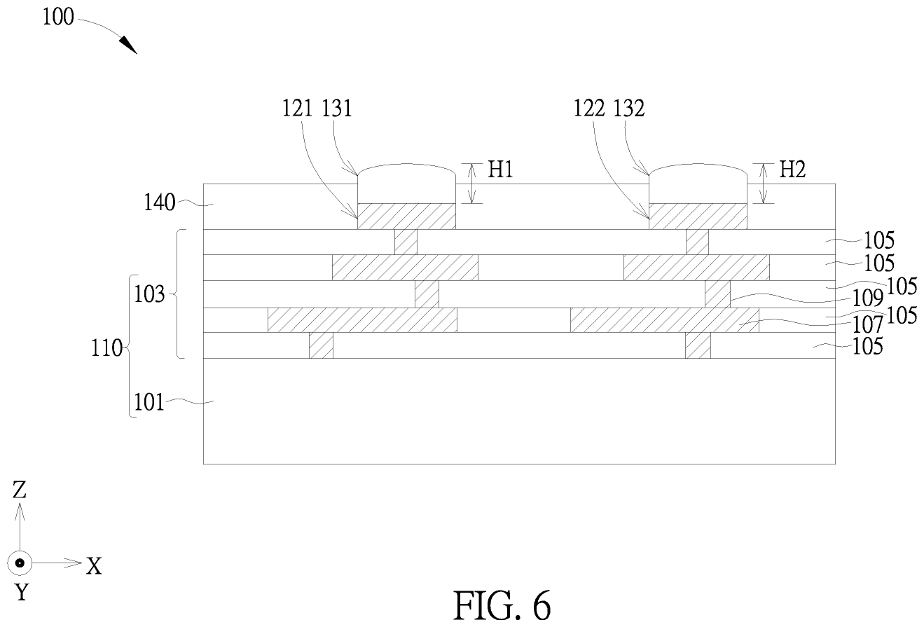

FIG. 6 illustrates a cross-sectional view of a semiconductor device in accordance with another embodiment of the present disclosure. The first electrode 121 and the second electrode 122 of the semiconductor device 100 in FIG. 6 are formed on a metal layer at the same horizontal height, so that the top surface of the first electrode 121 and the top surface of the second electrode 122 substantially have a same horizontal height. The first conductive bump 131 is formed on the first electrode 121, and the second conductive bump 132 is formed on the second electrode 122. According to an embodiment, the height H1 of the first conductive bump 131 and the height H2 of the second conductive bump 132 can be controlled by the manufacturing methods shown in FIGS. 1-2. In one embodiment, the height H1 of the first conductive bump 131 is the same as the height H2 of the second conductive bump 132 so that the top of the first convex top surface 131T of the first conductive bump 131 and the top of the second convex top surface 132T of the second conductive bump 132 substantially have a same horizontal height. In another embodiment, the height H1 of the first conductive bump 131 is different from the height H2 of the second conductive bump 132 so that the top of the first convex top surface 131T of the first conductive bump 131 is lower or higher than the top of the second convex top surface 132T of the second conductive bump 132.

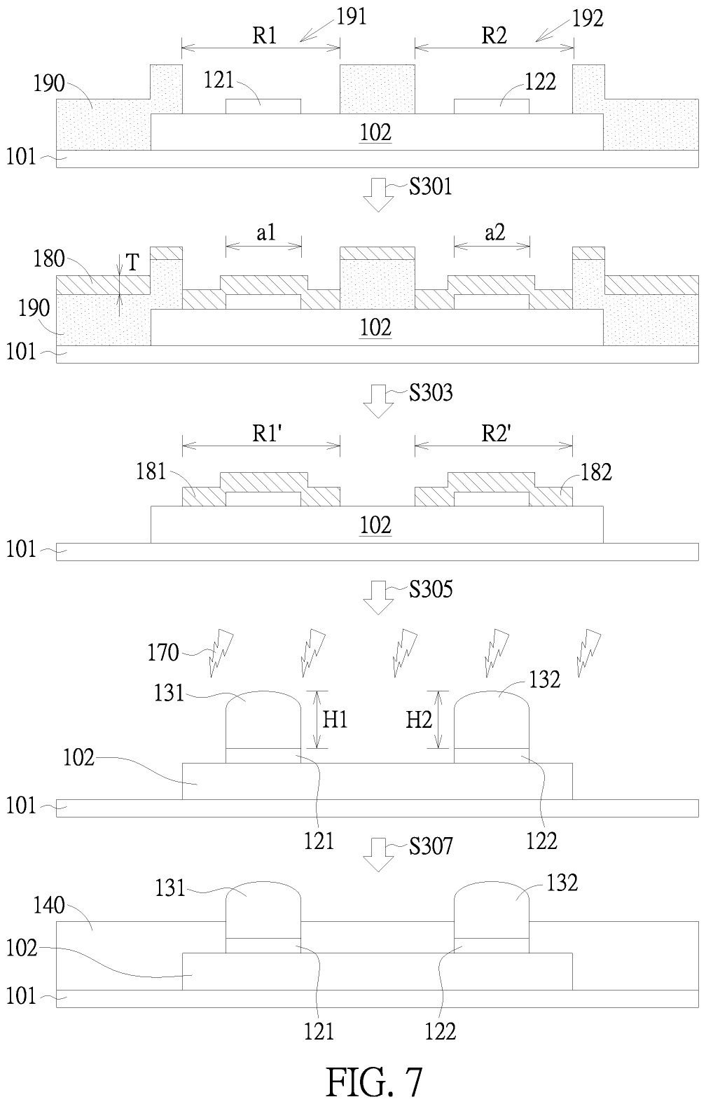

FIG. 7 illustrates a cross-sectional view of some stages of one manufacturing method of a semiconductor device in accordance with another embodiment of the present disclosure. First, a carrier 101 is provided, a semiconductor chip 102 is formed on the carrier 101, and a first electrode 121 and a second electrode 122 are formed on the same side of the semiconductor chip 102.

Then, a photoresist layer 190 is formed on the carrier 101 and the semiconductor chip 102 by using a photolithography process. The photoresist layer 190 includes a first opening 191 and a second opening 192 exposing the first electrode 121, the second electrode 122, and portions of the semiconductor chip 102 around the first electrode 121 and the second electrode 122, respectively. In one embodiment, the first opening 191 includes a first area R1, and the second opening 192 includes a second area R2. The first area R1 refers to a projected area of the first opening 191 on the carrier 101 or an area of the first opening 191 in an upper view of the semi-finished semiconductor device, and the second area R2 refers to a projected area of the second opening 192 on the carrier 101 or an area of the second opening 192 in an upper view of the semi-finished semiconductor device.

Then, in the step S301, a metal material layer 180 with a thickness T can be deposited conformally on the patterned photoresist layer 190 and in the first opening 191 and the second opening 192 by evaporation process. Except the discontinuity at the boundaries of the first opening 191 and the second opening 192, the metal material layer 180 is continuously extended on the patterned photoresist layer 190 and portions of the semiconductor chip 102 in the first opening 191 and the second opening 192.

Then, in step S303, the patterned photoresist layer 190 is removed, leaving a first metal layer 181 on the first electrode 121 and a second metal layer 182 on the second electrode 122. Wherein, the first metal layer 181 has a first area R1′ that is substantially identical to the first opening 191, and the second metal layer 182 has a second area R2′ that is substantially identical to the second opening 192. The first area R1′ refers to a projected area of the first metal layer 181 on the carrier 101 and the second area R2′ refers to a projected area of the second metal layer 182 on the carrier 101. According to one embodiment, the first electrode 121 has a first area a1, the second electrode 122 has a second area a2, the first area R1 is greater than the first area a1, and the second area R2 is greater than the second area a2. The first area a1 refers to a projected area of the first electrode 121 on the carrier 101 or an area of the first electrode 121 in an upper view of the semi-finished semiconductor device, and the second area a2 refers to a projected area of the second electrode 122 on the carrier 101 or an area of the second electrode 122 in an upper view of the semi-finished semiconductor device.

Then, in step S305, an energy 170 is provided to irradiate and heat the first metal layer 181, the second metal layer 182, the first electrode 121, and the second electrode 122 to form a first conductive bump 131 on the first electrode 121 and a second conductive bump 132 on the second electrode 122. The conditions of applying energy 170 can be referred to the above relevant paragraphs in step S103. During the heating process, the first metal layer 181 aggregates toward the first electrode 121, and the second metal layer 182 aggregates toward the second electrode 122. After the heating process is finished, the first conductive bump 131 and the second conductive bump 132 are each cured to form outer convex top surfaces. In step S307, a dielectric layer 140 can be optionally formed on the carrier 101 and the semiconductor chip 102. In one embodiment, the dielectric layer 140 surrounds all the sidewall(s) of the first electrode 121 and all the sidewall(s) of the second electrode 122, but only surrounds a portion of all the sidewall(s) of the first conductive bump 131 and a portion of all the sidewall(s) of the second conductive bump 132. In another embodiment, the dielectric layer 140 does not exist or surrounds only a portion of all the sidewall(s) of the first electrode 121 and a portion of all the sidewall(s) of the second electrode 122.

According to one embodiment, the first area R1′ of the first metal layer 181 can be changed by adjusting the size of the first opening 191 on the photoresist layer 190, so that the height H1 of the first conductive bump 131 can be further controlled; the second area R2′ of the second metal layer 182 can be changed by adjusting the size of the second opening 192 on the photoresist layer 190, so that the height H2 of the second conductive bump 132 can be further controlled. Wherein, when the projected areas of the first opening 191 and the second opening 192 are larger, the height H1 of the first conductive bump 131 and the height H2 of the second conductive bump 132 are higher. In one embodiment, the height H1 of the first conductive bump 131 and the height H2 of the second conductive bump 132 are substantially the same. In another embodiment, the height H1 of the first conductive bump 131 and the height H2 of the second conductive bump 132 are different.

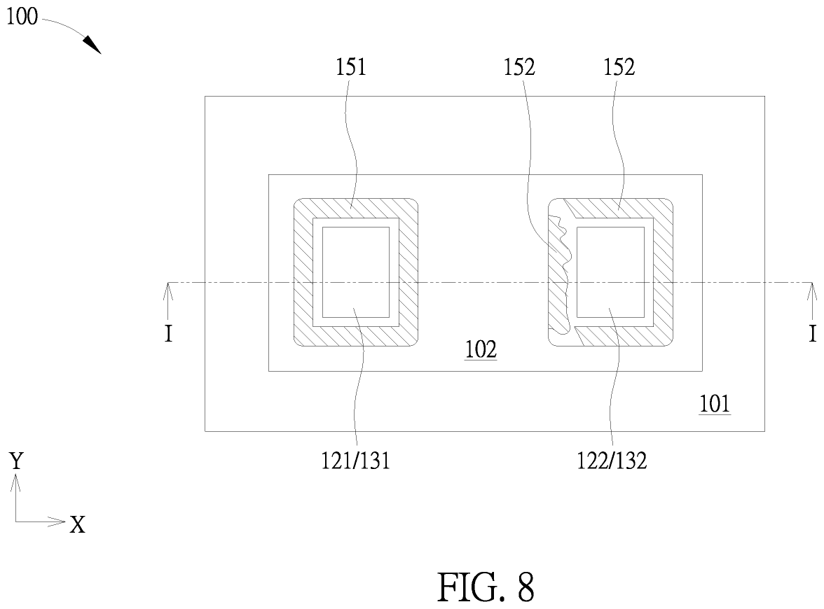

FIG. 8 illustrates an upper view of a semiconductor device in accordance with one embodiment of the present disclosure. As shown in FIG. 8, in one embodiment, the semiconductor device 100 formed by the manufacturing method shown in FIG. 7 further includes a first metal film 151 continuously located around the periphery of the first conductive bump 131 and a second metal film 152 discretely located at the periphery of the second conductive bump 132. As shown in FIG. 8, in one embodiment, when the thicknesses of the first metal film 151 and the second metal film 152 are thin, the cohesion between the metal film and the conductive bump is weak. Therefore, a discontinuous surface may be formed easily at the place where there is a height difference. For example, there may be a discontinuous gap between the first metal film 151 and the first conductive bump 131, and there may be a discontinuous gap between the second metal film 152 and the second conductive bump 132. In another embodiment, when the thicknesses of the first metal film 151 and the second metal film 152 are thick, the cohesion between the metal film and the conductive bump is strong, so it is not easy to form a discontinuous surface where there is a height difference. For example, there may be no discontinuous gap between the first metal film 151 and the first conductive bump 131, and there may be no discontinuous gap between the second metal film 152 and the second conductive bump 132.

The first metal film 151 and the second metal film 152 are formed through steps S303 to S305 as shown in FIG. 7. When the first metal layer 181 is aggregated on the first electrode 121 to form a first conductive bump 131, a metal film (the first metal film 151) remains on the upper surface of the semiconductor chip 102. When the second metal layer 182 is aggregated on the second electrode 122 to form a second conductive bump 132, a metal film (the second metal film 152) remains on the upper surface of the semiconductor chip 102. Therefore, the compositions of the first metal film 151 and the second metal film 152 contain the compositions of the first metal layer 181 and the second metal layer 182, respectively. In other words, the compositions of the first metal film 151 and the second metal film 152 contain the same metal as the main compositions of the first conductive bump 131 and the second conductive bump 132. In one embodiment, the compositions of the first metal layer 181 and the second metal layer 182 include a second metal (Sn), the main compositions of the first conductive bump 131 and the second conductive bump 132 include the second metal (Sn), and the compositions of the first metal film 151 and the second metal film 152 also include the second metal (Sn).

In addition, as shown in the FIG. 8, the first conductive bump 131 has a first outer contour, the first metal film 151 has a second outer contour, and the first outer contour is located inside and approximate to the second outer contour. The first metal film 151 may be a continuous or discontinuous film, which is continuously arranged around or discretely arranged at the periphery of the first electrode 121 or the first conductive bump 131. The second conductive bump 132 has a third outer contour, the second metal film 152 has a fourth outer contour, and the third outer contour is located inside and approximate to the fourth outer contour. The second metal film 152 may be a continuous or discontinuous film layer, which is continuously arranged around or discretely arranged at the periphery of the second electrode 122 or the second conductive bump 132. In the figure, the first metal film 151 arranged around the periphery of the first conductive bump 131 is an illustratively continuous film, and the second metal film 152 arranged at the periphery of the second conductive bump 132 is an illustratively discontinuous film. However, the embodiment is not limited to the present disclosure, and the metal films 151, 152 surrounding the conductive bumps 131, 132 may both be continuous or discontinuous films.

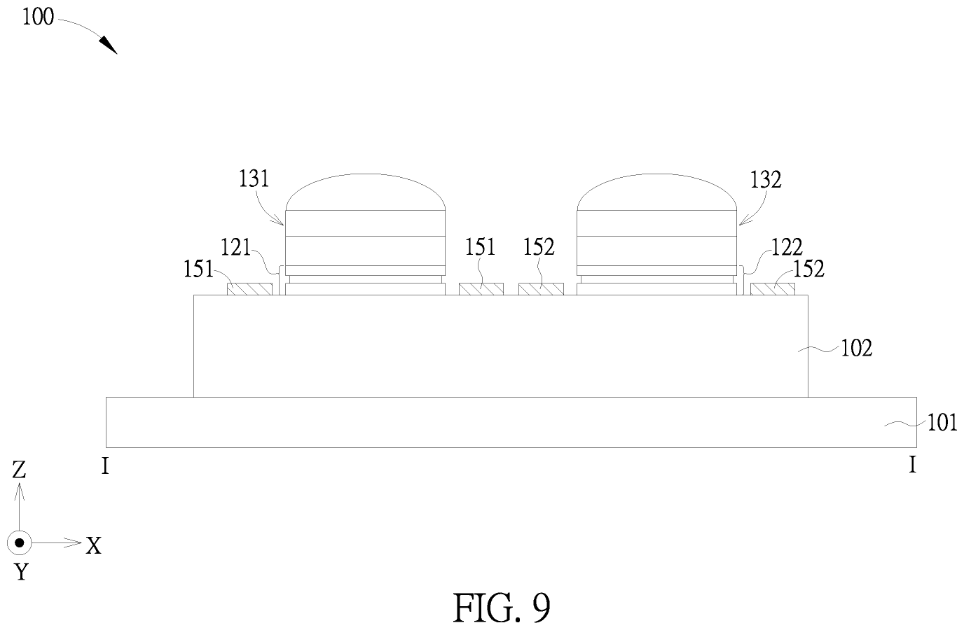

FIG. 9 illustrates a cross-sectional view of a semiconductor device along the line segment I-I of FIG. 8 in accordance with an embodiment of the present disclosure. As shown in FIG. 9, the first metal film 151 and the second metal film 152 are located on a surface of the semiconductor chip 102, the first metal film 151 is adjacent to one side of the first electrode 121, and the second metal film 152 is adjacent to one side of the second electrode 122. In one embodiment, the thickness of the first metal film 151 is 0.02 to 0.05 times the thickness of the first electrode 121, and the thickness of the second metal film 152 is 0.02 to 0.05 times the thickness of the second electrode 122. For example, both the thicknesses of the first metal film 151 and the second metal film 152 are about 0.1 microns (μm), and the total thicknesses of the first electrode 121 and the second electrode 122 are about 2 μm to 5 μm.

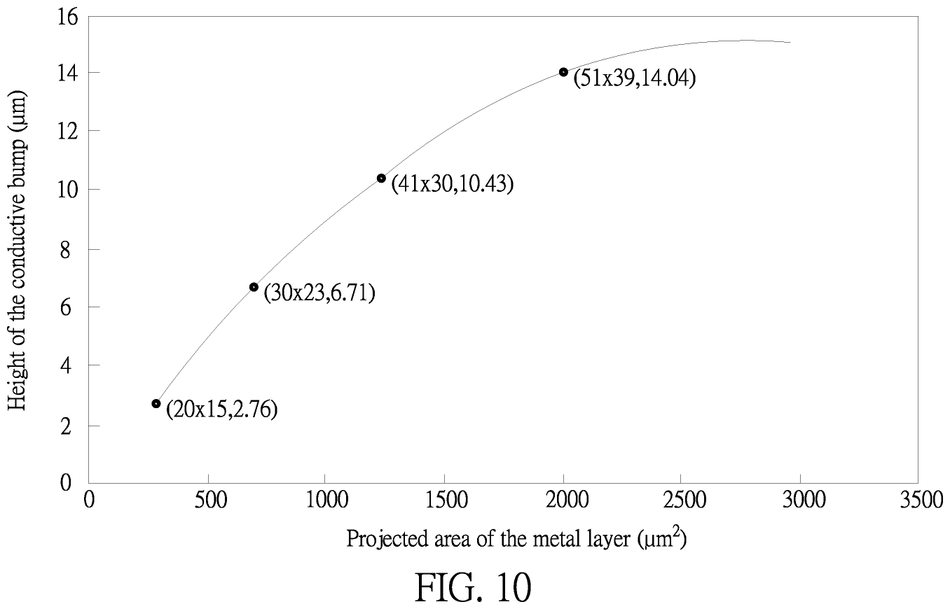

FIG. 10 illustrates a graph of the heights of the conductive bumps of a semiconductor device corresponding to the projected areas of the metal layers in accordance with some embodiments of the present disclosure. Wherein the conductive bump is the first conductive bump 131 or the second conductive bump 132 described above, and the height of the conductive bump is a distance from the bottom surface of the first conductive bump 131 or the second conductive bump 132 to the top of the top surface of the outer convex bump, for example, the height H1 of the first conductive bump 131 or the height H2 of the second conductive bump 132. The metal layer is, for example, the first metal layer 181 or the second metal layer 182 described above, and the projected area of the metal layer is, for example, the first area R1′ of the first metal layer 181 or the second area R2′ of the second metal layer 182. In the case where the projected area of the electrode is fixed, as shown in FIG. 10, the height of the conductive bump increases as the projected area of the metal layer increases. In one embodiment, taking the first area R1′ of the first metal layer 181, the first area a1 of the first electrode 121, the thickness T1/T of the first metal layer 181, and the height H1 of the first conductive bump 131 as examples, when the first area R1′ of the first metal layer 181 is 20×15 μm², 30×23 μm², 41×30 μm², and 51×39 μm², the first area a1 of the first electrode 121 is 20×15 μm², the thickness T1/T of the first metal layer 181 is 2 μm, and the height H1 of the first conductive bump 131 is 2.76 μm, 6.71 μm, 10.43 μm, and 14.04 μm.

According to some embodiments of the present disclosure, since the conductive bump is formed through the cohesion between the metal layer and the electrode, a saturation height of the conductive bump (the maximum height that can be formed) is related to the projected area of the electrode and/or the length of the short side of the electrode. In some embodiments, when the projected area of the electrode is 300 μm² , the saturation height of the conductive bump is about 15 μm. In other words, the saturation height of the first conductive bump 131 is smaller than or equal to 0.05 times of the first area a1 of the first electrode 121, and the saturation height of the second conductive bump 132 is smaller than or equal to 0.05 times of the second area a2 of the second electrode 122. In some embodiments, the saturation height of the first conductive bump 131 is smaller than or equal to a short side length of the first electrode 121, and the saturation height of the second conductive bump 132 is smaller than or equal to a short side length of the second electrode 122.

According to the embodiments of the present disclosure, the height of the conductive bump can be precisely controlled by adjusting the projected area and thickness of the metal layer, the amount of conductive glue applied, or the projected area and depth of the opening of the electrode exposed by the dielectric layer, so that the top of the conductive bump on each electrode can be roughly at the same horizontal height, or the height of the conductive bump on each electrode can reach its required height according to the needs of the semiconductor device. The manufacturing steps of the embodiments disclosed in the present disclosure are simplified and the cost is reduced, and can be controlled more accurately, which are suitable for the fabrication of conductive bumps on the electrodes of light-emitting diode chips or the fabrication of conductive bumps on the electrodes of RDL of semiconductor devices, and is particularly conducive to the mass transfer technology of light-emitting diode chips, so as to improve the manufacturing yield of light-emitting diode chips and reduce costs.

Although some embodiments of the present disclosure and their advantages have been described in detail, various changes, substitutions and alterations can be made herein without departing from the spirit and scope of the disclosure as defined by the appended claims.

What is claimed is:

1. A semiconductor device, comprising:
a substrate;
a first electrode and a second electrode, disposed on the substrate;
a first conductive bump, disposed on the first electrode; and
a second conductive bump, disposed on the second electrode,
wherein, the first conductive bump comprises a first convex top surface, the second conductive bump comprises a second convex top surface, and a top of the first convex top surface and a top of the second convex top surface are substantially including a same horizontal height; and
wherein, the compositions of the first electrode and the second electrode comprise a first metal, the compositions of the first conductive bump and the second conductive bump comprise the first metal and a second metal, and the content of the first metal in the first conductive bump is gradually decreased in a direction away from the first electrode.

2. The semiconductor device according to claim 1, wherein the first metal is Au and the second metal is Sn.

3. The semiconductor device according to claim 1, further comprising a dielectric layer disposed on the substrate and surrounding the first electrode and the second electrode.

4. The semiconductor device according to claim 3, wherein the dielectric layer surrounds the first conductive bump and the second conductive bump.

5. The semiconductor device according to claim 1, wherein the substrate comprises several dielectric layers or several metal layers.

6. The semiconductor device according to claim 5, further comprising a through hole in one of the several dielectric layers.

7. The semiconductor device according to claim 1, further comprising a first metal film located at one side of the first conductive bump and a second metal film at one side of the second conductive bump, wherein in an upper view, the first conductive bump has a first outer contour, the first metal film has a second outer contour, and the first outer contour is located inside the second outer contour and is approximate to the second outer contour.

8. The semiconductor device according to claim 1, wherein the first electrode comprises an Al-containing layer, and the first electrode is concave inward at the Al-containing layer.

9. The semiconductor device according to claim 1, where a height of the first conductive bump is smaller than or equal to 0.05 times a projected area of the first electrode.

10. The semiconductor device according to claim 1, wherein the first electrode comprises a short side, and a height of the first conductive bump is less than or equal to a length of the short side of the first electrode.

11. A semiconductor device, comprising:
a substrate;
a first electrode and a second electrode, disposed on the substrate;
a first conductive bump, disposed on the first electrode;
a second conductive bump, disposed on the second electrode;
a first metal film, located at one side of the first conductive bump; and
a second metal film, located at one side of the second conductive bump.

12. The semiconductor device according to claim 11, wherein in an upper view, the first metal film is a discontinuous film.

13. The semiconductor device according to claim 11, wherein the first metal film comprises a first metal, the first conductive bump comprises a second metal, and the first metal and the second metal are the same.

14. The semiconductor device according to claim 11, wherein a thickness of the first metal film is 0.02 to 0.05 times a thickness of the first electrode, and a thickness of the second metal film is 0.02 to 0.05 times a thickness of the second electrode.

15. The semiconductor device according to claim 11, wherein the first electrode comprises a short side, and a height of the first conductive bump is less than or equal to a length of the short side of the first electrode.

16. A method of manufacturing a semiconductor device, comprising:
providing a semiconductor chip, and the semiconductor chip comprising a first electrode and a second electrode;
forming a first metal layer on the first electrode, the first metal layer comprising a first part and a second part, in an upper view, the first part overlapping the first electrode, and the second part not overlapping the first electrode; and
heating the first metal layer so that a thickness of the first part increasing and a thickness of the second part decreasing.

17. The method of manufacturing a semiconductor device according to claim 16, further comprising:
forming a second electrode on the semiconductor chip;
forming a dielectric layer on the semiconductor chip, the dielectric layer comprising a first hole and a second hole which expose the first electrode and the second electrode, respectively;
forming a second metal layer on the second electrode, the second metal layer comprising a third part and a fourth part, in the upper view, the third part overlapping the second electrode, and the fourth part not overlapping the second electrode;
filling a glue into the first hole and the second hole; and
applying an energy to the glue, the first metal layer and the second metal layer to form a first conductive bump on the first electrode and a second conductive bump on the second electrode.

18. The method of manufacturing a semiconductor device according to claim 17, wherein a total volume of the first conductive bump is greater than that of the first hole, and the total volume of the second conductive bump is greater than that of the second hole.

19. The method of manufacturing a semiconductor device according to claim 16, further comprising the method of manufacturing the first metal layer, comprising:
forming a patterned photoresist layer on the semiconductor chip, and the patterned photoresist layer comprising a first opening to expose the first electrode;
forming a metal layer on the patterned photoresist layer and in the first opening; and
peeling off the patterned photoresist layer to leave a portion of the first metal layer.

20. The method of manufacturing a semiconductor device according to claim 16, wherein the first electrode comprises a first metal, the composition of the first metal layer comprises a second metal, and the composition of the first conductive bump comprises the first metal and the second metal.
